(19) United States
(12) Patent Application Publication
(10) Pub. No.: US 2025/0269592 A1
(43) Pub. Date: Aug. 28, 2025

(54) APPARATUS FOR NANOMATERIAL GENERATION AND PRINTING

(71) Applicant: Oregon State University, Corvallis, OR (US)

(72) Inventors: Chih-Hung Chang, Corvallis, OR (US); Venkata Vinay Krishna Doddapaneni, Corvallis, OR (US); Chuankai Song, Corvallis, OR (US); Brian K. Paul, Corvallis, OR (US); Jeffrey Arul Dhas, Corvallis, OR (US); Somayeh Pasebani, Corvallis, OR (US)

(73) Assignee: Oregon State University, Corvallis, OR (US)

(21) Appl. No.: 19/060,433

(22) Filed: Feb. 21, 2025

Related U.S. Application Data
(60) Provisional application No. 63/556,805, filed on Feb. 22, 2024.

(51) Int. Cl. B29C 64/209; B29C 64/165; B29C 64/273; B33Y 10/00; B33Y 30/00; B33Y 80/00; B82Y 30/00; B82Y 40/00

(52) U.S. Cl. CPC B29C 64/209; B29C 64/165; B29C 64/273; B33Y 10/00; B33Y 30/00; B33Y 80/00; B82Y 30/00; B82Y 40/00

(57) ABSTRACT

Disclosed herein is an optical printhead for producing nanoparticles, comprising a reaction module, the reaction module comprising a mixing chamber. One or more inlets open into the mixing chamber, wherein a nozzle is coupled to the mixing chamber. The printhead further comprises an optical module that extends into the reaction module. The optical module comprises an optical lens and a light source aligned to the optical lens, wherein the lumen opens into the mixing chamber.

### CLAIM FOR PRIORITY

This application claims priority to U.S. Provisional Patent Application No. 63/556,805, filed on Feb. 22, 2024, titled “APPARATUS FOR NANOMATERIAL GENERATION AND PRINTING,” which is incorporated by reference in its entirety for all purposes.

### STATEMENT OF GOVERNMENT INTEREST

This invention was made with government support awarded by National Science Foundation, award number 1941262. The government has certain rights in the invention.

### BACKGROUND

Metal additive manufacturing has created new opportunities to design and fabricate new multifunctional materials by doping secondary phases to improve the functional properties or doing nanoparticles to strengthen the alloys. These involve pre-mixing two materials by mechanical ball milling or acoustic mixing, and thus use more extended time and energy. Solvent-based inkjet printing was used to jet the nanoparticles into stainless steel to generate oxide dispersion strengthened (ODS) alloys. However, there are multiple challenges with solvent use in a laser-based 3D printers such as laser powder bed fusion (LPBF) or Laser Direct Energy Deposition (LDED) techniques.

### BRIEF DESCRIPTION OF DRAWINGS

Material described herein is illustrated by way of example and not by way of limitation in accompanying figures. For simplicity and clarity of illustration, elements illustrated in figures are not necessarily drawn to scale. For example, dimensions of some elements may be exaggerated relative to other elements for clarity. Also, various physical features may be represented in their simplified “ideal” forms and geometries for clarity of discussion, but it is nevertheless to be understood that practical implementations may approximate illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among figures to indicate corresponding or analogous elements.

FIG. 1 illustrates a cross-sectional view of an optical printhead assembly, in accordance with at least one implementation.

FIG. 2 illustrates a cross-sectional view of an optical printhead assembly comprising a contiguous sidewall mixing chamber and nozzle portion, in accordance with at least one implementation.

FIG. 3 illustrates a cross-sectional view of an optical printhead assembly comprising an axicon lens, in accordance with at least one implementation.

FIG. 4 illustrates a cross-sectional view of an optical printhead configured to illuminate a substrate surface simultaneously with deposition of nanoparticles for heterogeneous nanoparticle film formation, in accordance with at least one implementation.

FIG. 5 illustrates a cross-sectional view of an optical printhead assembly configured to illuminate a substrate surface simultaneously with deposition of nanoparticles for heterogeneous nanoparticle film formation, in accordance with at least one implementation.

FIG. 6 illustrates a cross-sectional view of an optical printhead assembly, comprising optics module and separate precursor delivery module, in accordance with at least one implementation.

FIG. 7A illustrates a cross-sectional view of a dual illumination-zone optical printhead assembly comprising an optical furnace, in accordance with at least one implementation.

FIG. 7B illustrates a cross-sectional view of dual illumination-zone optical printhead assembly comprising one or more collimating lenses mounted within optical ports disposed within a sidewall of the optical furnace, in accordance with at least one implementation.

FIG. 8 illustrates an optical nanoparticle printer system in accordance with at least one implementation.

FIG. 9 shows a flowchart illustrating a method for writing nanoparticle patterns on substrates, in accordance with at least one implementation.

FIG. 10 illustrates a processor system with a machine-readable storage medium having machine-readable instructions that when executed cause a microcontroller in a circuit board of a control unit for the optical nanoparticle printer shown in FIG. 8 to execute machine-readable instructions according to the method described in FIG. 9, in accordance with at least one implementation.

### DETAILED DESCRIPTION

Gas-phase homogeneous synthesis of nanomaterials has been studied by both physical and chemical synthesis methods such as pulsed laser ablation, spray pyrolysis, flame pyrolysis, gas condensation, chemical vapor synthesis, ion sputtering, laser pyrolysis, photothermal synthesis, thermal plasma synthesis, etc. For instance, chemical synthesis methods involve heating the precursor vapors by conventional thermal heating and electromagnetic radiation to decompose and generate the nanomaterials. Conventional thermal heating poses challenges as it uses hot-wall type configurations, and controlling the homogeneous reaction is cumbersome and results in low yields due to the deposition on the chamber walls. Electromagnetic radiation provides localized homogeneous gas-phase decomposition of precursor vapors by absorption of radiation by precursors or photosensitizers.

At least one implementation describes a printhead comprising integrated optics for 3D printing of inorganic and organic nanocrystalline structures. In at least one implementation, the printhead comprises an integrated optical light source aligned to direct a light beam through the integrated optics. In at least one implementation, the printhead comprises an optical port for coupling light from an external optical light source into the integrated optics, for example, by an optical fiber. In at least one implementation, the printhead comprises one or more gas/vapor inlet ports in fluid communication with a mixing chamber. In at least one implementation, the optical port comprises an optical system comprising at least one lens, where the optical system interfaces the optical chamber.

In at least one implementation, the optical system comprises a cylindrical lens. In at least one implementation, the optical system comprises a Powell lens. In at least one implementation, the optical system comprises an axicon lens. In at least one implementation, the optical system comprises a plano-convex lens or an aspheric lens. In at least one implementation, the optical lens may focus light within a reaction zone defined within the mixing chamber within the disclosed printhead. In at least one implementation, precursor molecules are transported into the mixing chamber by carrier gases.

In at least one implementation, precursor molecules entrained in a carrier gas stream may enter an illuminated reaction zone within the mixing chamber and undergo photochemical or thermochemical reactions. In at least one implementation, the reaction zone is illuminated by focused light from the optical light source and emanating from the optical lens. In at least one implementation, a single substance may be introduced into the mixing chamber, where the single precursor substance may undergo photochemical or thermochemical unimolecular or bimolecular reactions to form nanoparticles homogeneously in the gas stream. Alternatively, two or more substances may be introduced in a gaseous stream that may undergo photochemical or thermochemical bimolecular or trimolecular reactions to form nanoparticles homogeneously in the gas stream.

In at least one implementation, the printhead comprises a nozzle orifice extending from the mixing chamber to the exterior of the printhead. In at least one implementation, homogeneously formed nanoparticles entrained in the gas stream exit the mixing chamber through the nozzle to a surface adjacent to the orifice (e.g., below it). In at least one example, homogeneously formed nanoparticles may stream from the nozzle of the printhead and deposit on the surface to form printed structures.

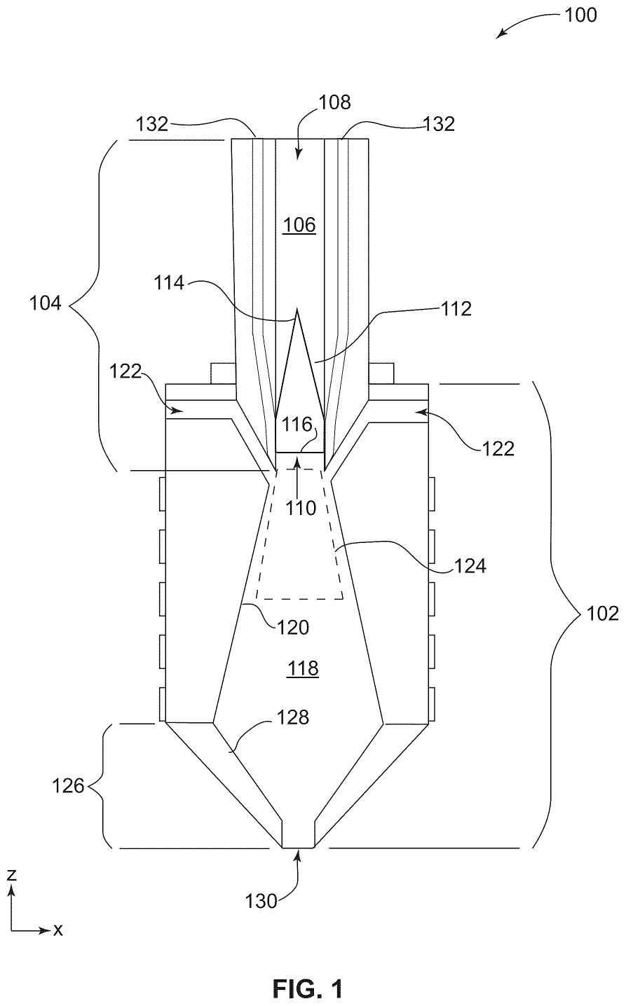

FIG. 1 illustrates a cross-sectional view of optical printhead assembly 100, in accordance with at least one implementation. Optical printhead assembly 100 comprises a reaction module 102 and an optics module 104 mechanically coupled to reaction module 102. In at least one implementation, optics module 104 is mounted over reaction module 102. In at least one implementation, reaction module 102 and optics module 104 may be cylindrical, being substantially symmetrical at all angles of rotation about the z-axis in the figure. In at least one implementation, reaction module 102 and optics module 104 may have a rectangular cross section, where the y-dimension of reaction module 102 extending above and below the plane of the figure is smaller than the x-dimension of reaction module 102. In at least one implementation, optics module 104 is detachable from reaction module 102. For example, optics module 104 may comprise a threaded base that screws into a receiving port within reaction module 102.

In at least one implementation, optics module 104 comprises lumen 106 extending from upper opening 108 to lower opening 110. In at least one implementation, upper opening 108 is configured to receive a light source module or an optical fiber from an external light source. In at least one implementation, optics module 104 further comprises lens 112 within lumen 106. In at least one implementation, lens 112 is disposed within lumen 106 vicinal to lower opening 110. In at least one implementation, lens 112 may be a Powell lens, as shown, having an apex 114 facing inward within lumen 106, and a flat surface opposite the apex. While the implementation shown in FIG. 1 illustrates a Powell lens as lens 112, other suitable lenses may be employed as lens 112. Further lens implementations are described below.

In at least one implementation, reaction module 102 comprises mixing chamber 118 within reaction module 102. In at least one implementation, a mixing chamber 118 is substantially coaxial with the cylindrical form factor of reaction module 102. In at least one implementation, a sidewall 120 of mixing chamber 118 is flared to permit gradual expansion of one or more gas streams entering mixing chamber 118 through precursor inlets 122, where precursor inlets 122 are in fluidic communication with mixing chamber 118. Gradual expansion of precursor gases may reduce the flow velocity of precursor molecules within mixing chamber 118 to increase residence time of precursor molecules within a reaction zone 124 for homogeneous generation of nanoparticles, for example.

In at least one implementation, reaction module 102 comprises a nozzle portion 126. In at least one implementation, nozzle portion 126 comprises a sidewall 128 that is flared inward. In at least one implementation, nozzle portion 126 terminates at a nozzle orifice 130. Gases passing through mixing chamber 118 are funneled through nozzle portion 126, where they may increase flow velocity and exit through a nozzle orifice 130 to the exterior as a gas stream.

In at least one implementation, lens 112 is operable to produce a quasi-two-dimensional light field emanating from a flat surface 116 of lens 112 and expanding into mixing chamber 118. In at least one implementation, reaction zone 124 may comprise a substantial portion of the light field produced by lens 112. In at least one implementation, precursor molecules passing through reaction zone 124 may undergo homogeneous photochemical reactions initiated within the light field of reaction zone 124 to form nanoparticles within mixing chamber 118.

In at least one implementation, optics module 104 comprises carrier gas inlets 132. In at least one implementation, carrier gas inlets 132 extend to precursor inlets 122, below lens 112. Carrier gas flowing through carrier gas inlets 132 may deflect precursor flow away from lens 112, mitigating fouling of surfaces of optical lens with nanoparticle films.

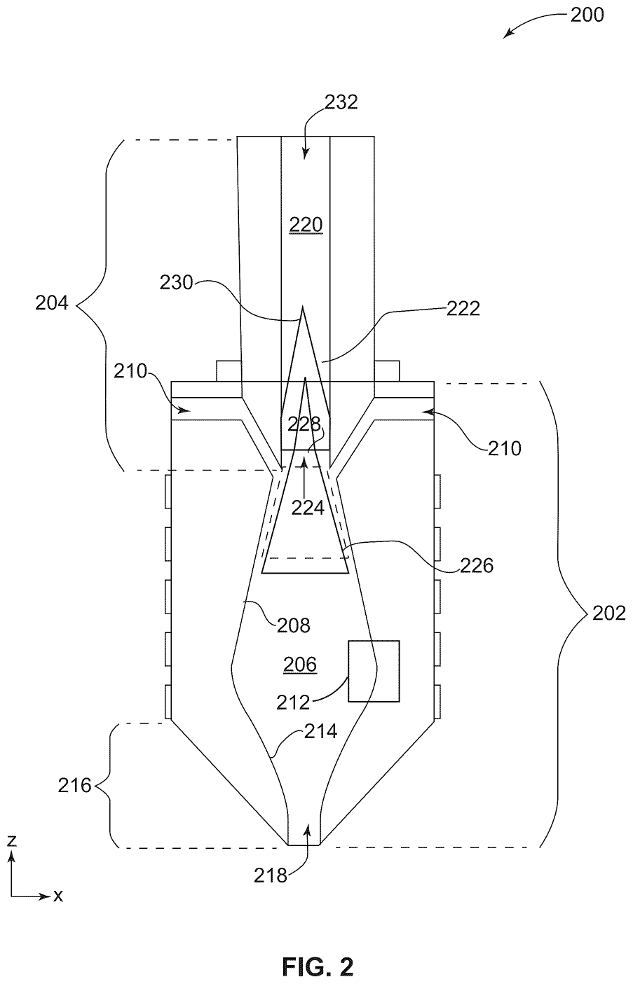

FIG. 2 illustrates a cross-sectional view of an optical printhead assembly 200 comprising a contiguous sidewall in a mixing chamber 206 and a nozzle portion, in accordance with at least one implementation. In at least one implementation, optical printhead assembly 200 comprises a reaction module 202 and an optics module 204. In at least one implementation, reaction module 202 and optics module 204 comprise a unitary body, where reaction module 202 and optics module 204 are machined from a single ingot or grown as a single object by additive manufacturing methods such as 3D printing. In at least one implementation, reaction module 202 and optics module 204 are separate units, where optical printhead assembly 200 is an assembly comprising optics module 204 attached to reaction module 202. Assembly implementations and means of attachment may be substantially similar to those described above for optical printhead assembly 100.

In at least one implementation, reaction module 202 comprises mixing chamber 206, centrally disposed within reaction module 202. In at least one implementation, optical printhead assembly 200 has a cylindrical form factor, where mixing chamber 206 is coaxial with reaction module 202 and optics module 204. In at least one implementation, optical printhead assembly 200 has a substantially rectangular cross section, where mixing chamber 206 is substantially aligned with a bisymmetrical axis of optical printhead assembly 200. In at least one implementation, mixing chamber 206 may be off-axis relative to reaction module 202.

In at least one implementation, mixing chamber 206 comprises sidewall 208. In at least one implementation, sidewall 208 is flared to enable expansion of gases introduced into mixing chamber via precursor inlets 210. In at least one implementation, sidewall 208 comprises a transition region 212 that smoothly transitions to sidewall 214 of nozzle portion 216. In at least one implementation, the curvature of transition region 212 mitigates a sharp transition from mixing chamber 206 to nozzle portion 216, reducing turbulence and promoting laminar flow of carrier gases flowing within reaction module 202.

In at least one implementation, sidewall 214 of nozzle portion 216 has a transitional convex curvature enabling a smooth convergence of gases in laminar flow toward nozzle orifice 218. In at least one implementation, the curvature of sidewall 214 may be adjusted for maximum performance according to flow velocity and dimensions of mixing chamber 206, nozzle portion 216, and nozzle orifice 218.

In at least one implementation, mixing chamber 206 is aligned with lumen 220 within optics module 204. In at least one implementation, optics module 204 comprises lens 222, shown disposed near lower opening 224 of lumen 220. In at least one implementation, lens 222 is a Powell lens, operable to form a quasi-two-dimensional light field 226 emanating from base surface 228 of lens 222. In at least one implementation, light field 226 has a substantially trapezoidal form factor. In at least one implementation, the expansion angle of light field 226 may be adjusted to substantially match flare angle of mixing chamber 206 for maximum efficiency of energy transfer by selection of appropriate dimensions of lens 222 (e.g. angle of lens apex 230).

In at least one implementation, upper opening 232 of lumen 220 is configured as an optical port to receive an optical fiber from an external light source. In at least one implementation, upper opening 232 is configured for direct attachment of a coherent light source (e.g., a modular laser) or non-coherent light source. In at least one implementation, upper opening 232 may comprise a threaded portion for engagement with a threaded mating portion of a modular light source. In at least one implementation, upper opening 232 may be configured to engage a bayonet-style attachment barrel or ring on a modular light source.

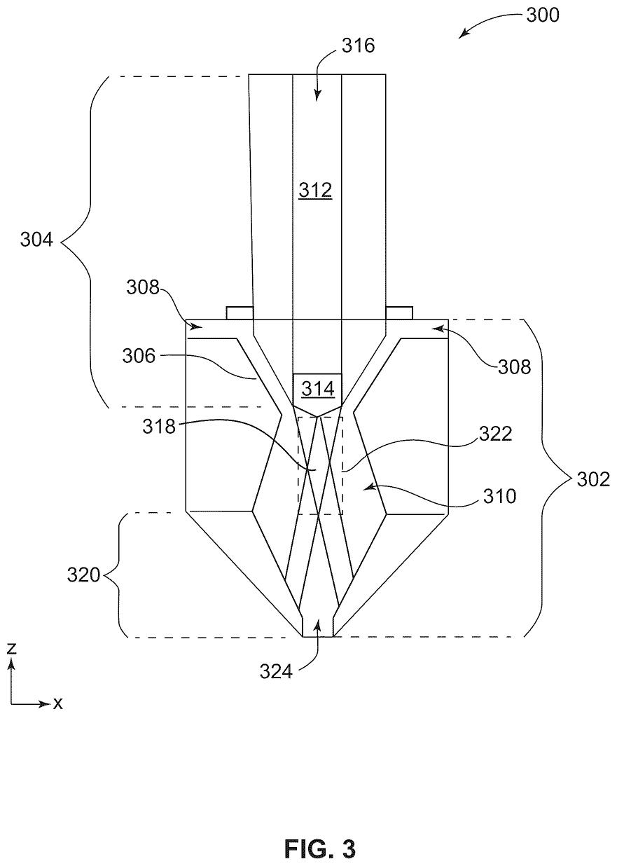

FIG. 3 illustrates an optical printhead assembly 300 comprising an axicon lens, in accordance with at least one implementation. In at least one implementation, optical printhead assembly 300 comprises reaction module 302 and optics module 304. In at least one implementation, optics module 304 is affixed to reaction module 302. In at least one implementation, optics module 304 is seated in a receptacle 306 on the top side of reaction module 302. In at least one implementation, a separation between optics module 304 and receptacle 306 enables a flow of reaction gas mixtures introduced at inlets 308 to flow to mixing chamber 310.

In at least one implementation, optics module 304 comprises lumen 312. Lens 314 is seated within lumen 312 proximal to mixing chamber 310. In at least one implementation, optics module 304 comprises upper opening 316 of lumen 312. In at least one implementation, upper opening 316 is configured as an optical port to receive an optical fiber from a light source (not shown). In at least one implementation, upper opening 316 is configured to receive a light source module (not shown) directly affixed to optics module 304. In at least one implementation, lens 314 may be an axicon lens, operable to focus light received from the light source into a light field 318 having an open conical geometry. In at least one implementation, light field 318 is hollow in a lower portion within nozzle 320, as shown, and a filled region at the intersection of angled beams within reaction zone 322, delineated by the dashed box. In at least one implementation, nanoparticles formed within reaction zone 322 may exit mixing chamber 310 through nozzle orifice 324.

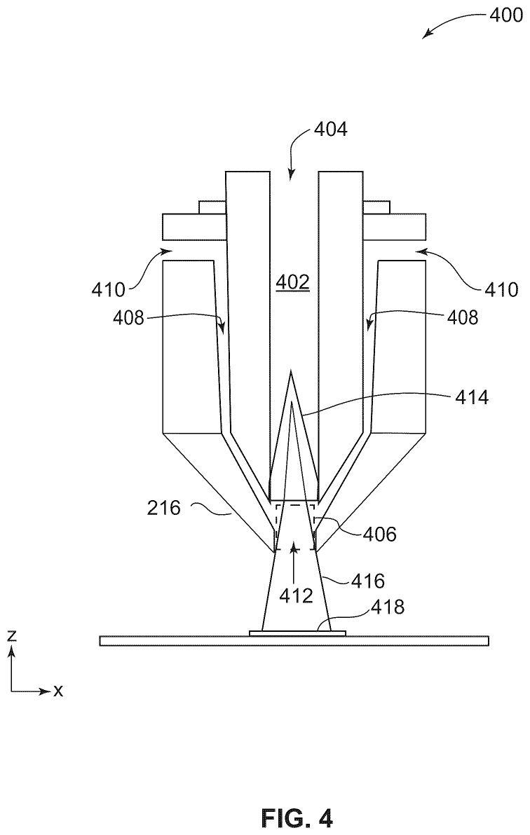

FIG. 4 illustrates a cross-sectional view of an optical printhead assembly 400, configured to illuminate a substrate surface simultaneously with deposition of incipient nanoparticles for heterogeneous nanoparticle film formation, in accordance with at least one implementation. In at least one implementation, optical printhead assembly 400 is configured to form nanoparticles externally by photoinitiated heterogeneous reactions. An internal mixing chamber for homogeneous nanoparticle production, such as mixing chamber 206, is omitted for optical printhead assembly 400. In at least one implementation, optical printhead assembly 400 comprises lumen 402 extending from upper opening 404 to plenum 406, delineated by the dashed box. In at least one implementation, conduits 408 extend from inlets 410 into plenum 406. In at least one implementation, plenum 406 opens to nozzle orifice 412. In at least one implementation, optical lens 414 is seated within lumen 402, positioned above plenum 406. In at least one implementation, optical lens 414 may be recessed into lumen 402 to avoid fouling of optical surfaces by formation of nanoparticles within plenum 406.

In at least one implementation, upper opening 404 of lumen 402 is configured as an optical port to receive an optical fiber (not shown) extending from an external light source. In at least one implementation, upper opening 404 is configured to receive a light source module that is operable to insert directly into lumen 402. In at least one implementation, optical lens 414 may be aligned to an optical fiber or light source module attached to optical printhead assembly 400. In at least one implementation, optical lens 414 is operable to create light field 416. In at least one implementation, light field 416 is substantially trapezoidal. In at least one implementation, light field 416 is quasi-two-dimensional, whereby light field 416 is flattened in the y-dimension (above and below the plane of the figure). In at least one implementation, light field 416 is conical. Conicity or flatness of light field 416 may be determined by optical lens 414. For example, optical lens 414 may be a Powell lens, operable to create trapezoidal quasi-two-dimensional light field. Light emanating from optical lens 414 may be focused in a line on substrate 418 because of light field 416 intersecting with substrate 418. In at least one implementation, optical lens 414 may be a hemi-cylindrical lens, also operable to create a quasi-two-dimensional light field, where the light field intersects substrate 418 at a line of focus. In at least one implementation, optical lens 414 may be a plano-convex lens, operable to create a conical shape of light field 416. A diffuse circle or tight spot of light may result from the intersection of conical light field and substrate 418. In at least one embodiment, optical lens 414 is an aspherical lens.

In at least one implementation, light field 416 may comprise visible or ultraviolet light having an optical spectrum capable of initiating photochemical reactions of precursor molecules entrained within carrier gases that pass into plenum 406 from conduits 408 and impinge on substrate 418. In at least one implementation, light field 416 may comprise infrared light capable of inducing thermochemical reactions of precursor molecules. In at least one implementation, intensity of light field 416 may be adjusted to ensure a desired reaction rate of nanoparticle production on substrate 418. In at least one implementation, precursor molecules passing through plenum 406 may nucleate by homogeneous reaction within light field 416 to form incipient nanoparticles. Such nanoparticles may continue to grow in the homogeneous phase while transiting through plenum 406 and nozzle orifice 412 and impinge on substrate 418. In at least one implementation, a gas stream exiting nozzle orifice 412 may also carry unreacted precursor molecules that also impinge on substrate 418. In at least one implementation, unreacted precursor molecules may undergo heterogeneous photochemical reactions on substrate 418 where it is illuminated by light field 416. In at least one implementation, on substrate 418, unreacted precursor molecules may photochemically and/or thermochemically form new nanoparticles heterogeneously in or grow nanoparticles from nuclei homogeneously formed in the gas phase. In at least one implementation, substrate 418 is heated to increase rates of surface reactions.

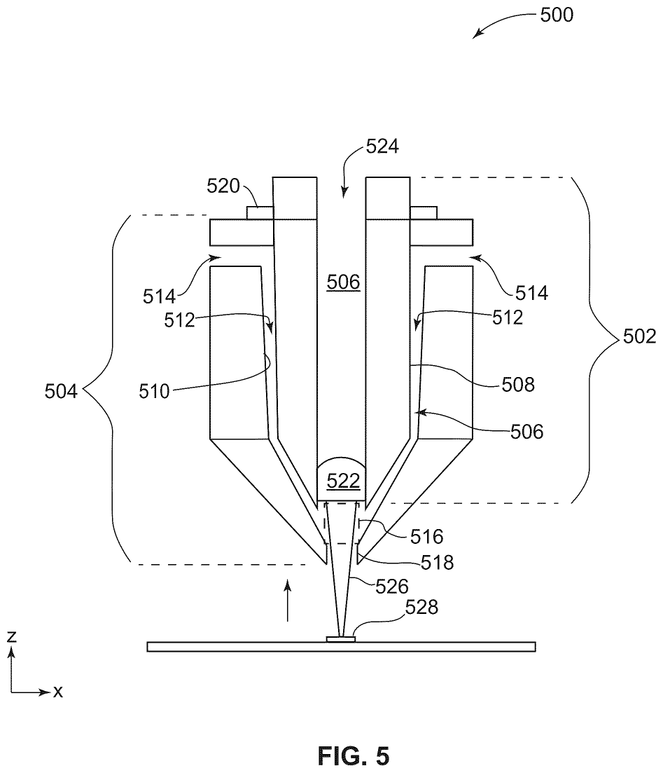

FIG. 5 illustrates a cross-sectional view of an optical printhead assembly 500, comprising an optics module 502 and a gas flow module 504 and configured to illuminate a substrate surface simultaneously with deposition of nanoparticles for heterogeneous nanoparticle film formation, in accordance with at least one implementation. In at least one implementation, optics module 502 inserts into gas flow module 504 forming an assembly comprising optics module 502 and gas flow module 504. In at least one implementation, gas flow module 504 comprises a lumen 506, into which optics module 502 may be inserted. In at least one implementation, when seated within gas flow module 504, an outer wall 508 of optics module 502 and/or an inner wall 510 of gas flow module 504 may be recessed such that conduit channels, such as conduits 512 may be formed for conduction of precursor gases and/or carrier gases from inlets 514 to a plenum 516. Gas flow module 504 comprises a nozzle orifice 518 below plenum 516. While two inlets 514 are shown in the figure, gas flow module 504 may comprise three or more inlets 514. In at least one implementation, outer wall 508 and inner wall 510 are fully separated, forming an interwall space between outer wall 508 and inner wall 510 of optics module 502 and gas flow module 504, respectively. In the figure, the interwall space is not referenced by number, but may be depicted in cross section as conduit 512 surrounding optics module 502. In at least one implementation, the interwall space may have fluidic communication with inlets 514 and plenum 516. In at least one implementation, the interwall space may be operable to conduct gases that enter from inlets 514 to plenum 516.

In at least one implementation, optics module 502 comprises a collar 520 for limiting the depth of insertion of optics module 502 into lumen 506 of gas flow module 504 to maintain a desired distance between outer wall 508 and inner wall 510. In at least one implementation, other structures may be present to stabilize the separation distance between optics module 502 and gas flow module 504. In at least one implementation, lumen 506 is aligned with plenum 516 to provide optical alignment of lens 522 with nozzle orifice 518. In at least one implementation, upper opening 524 of lumen 506 is configured as an optical port to receive an optical fiber (not shown). In at least one implementation, upper opening 524 is configured to receive a light module (not shown) operable to produce collimated (e.g., laser) or non-collimated light. In at least one implementation, the light supplied by the light source may comprise infrared, visible, and/or ultraviolet wavelengths at sufficient intensity to initiate photochemical reactions of precursor molecules.

In at least one implementation, lens 522 is a plano-convex lens, as shown. While a plano-convex lens is shown in FIG. 5, other suitable types of lenses may be employed. For example, a cylindrical lens, an axicon lens or a Powell lens may be employed. A plano-convex lens having a cylindrical or rectangular form factor may provide a conical light field 526 that impinges on substrate 528. In at least one implementation, light field 526 may be focused to form a circular or rectangular focused spot, respectively, of light on substrate 528. In at least one implementation, a plano-convex lens may be inverted to defocus a collimated beam from a laser to a larger and more diffuse region, allowing a greater reactive cross section for nanoparticle production on substrate 528 relative to a focused spot. In at least one implementation, optical printhead assembly 500 may be raster scanned over substrate 528 to write nanoparticle patterns.

In at least one implementation, unreacted precursor molecules may be entrained in a carrier gas flow that exits through nozzle orifice 518 and flows in a jet stream toward substrate 528. Unreacted precursor molecules impinging on substrate 528 within the illuminated region of substrate 528 may under heterogeneous photoreactions on substrate 528 that are stimulated by visible or ultraviolet wavelengths from the external laser or non-collimated light source.

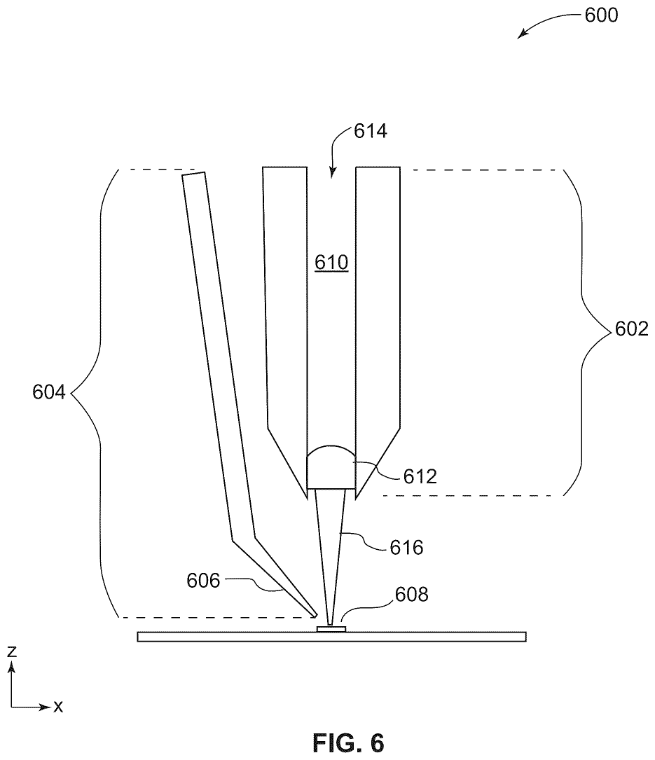

FIG. 6 illustrates a cross-sectional view of a printhead assembly 600, comprising an optics module 602 and a precursor delivery module 604, in accordance with at least one implementation. In at least one implementation, precursor delivery module 604 is not coaxial with optics module. In at least one implementation, precursor delivery module 604 is laterally disposed with respect to optics module 602.

In at least one implementation, precursor delivery module 604 is configured as a tube comprising a nozzle 606. In at least one implementation, nozzle 606 may terminate near a substrate 608. In at least one implementation, precursor delivery module 604 is coupled to a precursor gas source, comprising a carrier gas. In at least one implementation, nozzle 606 comprises an orifice (not shown) whose diameter may be engineered to adjust the flow rate of a precursor/carrier gas mixture.

In at least one implementation, optics module 602 comprises a lumen 610, where a lens 612 is seated within a lower portion of lumen 610. In at least one implementation, an upper opening 614 is configured to receive an optical fiber (not shown) or a light source module (not shown). In at least one implementation, lens 612 is a plano-convex lens, configured to develop a conical light field, such as light field 616. In at least one implementation, lens 612 may focus collimated or uncollimated light to a small spot impinging on substrate 608. In at least one implementation, lens 612 may be inverted to defocus light into a diffuse larger spot.

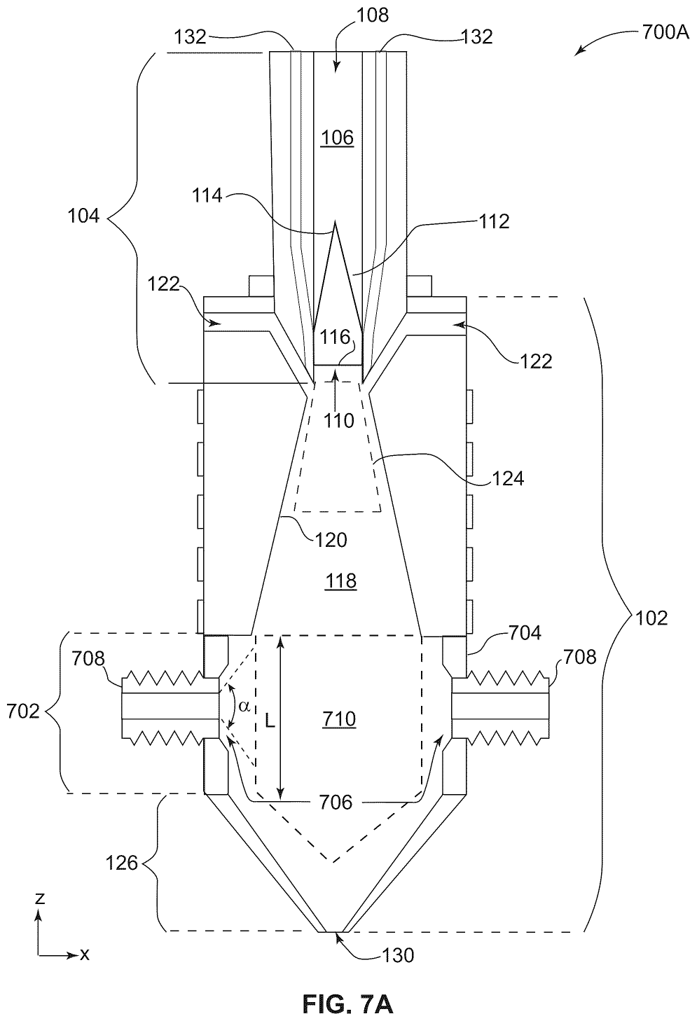

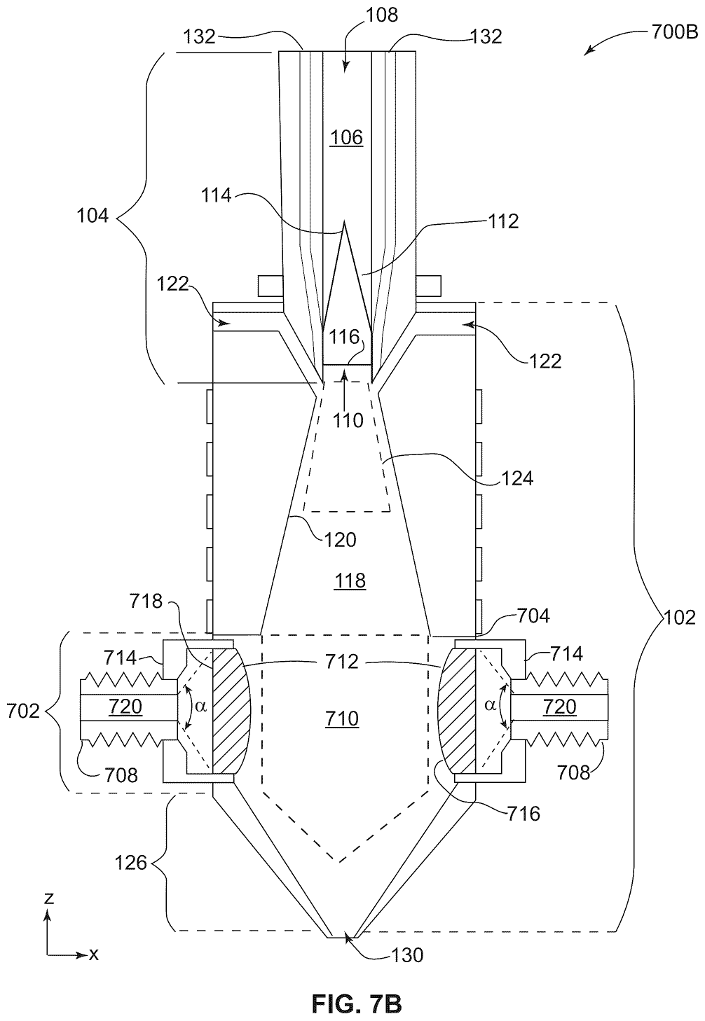

FIG. 7A illustrates a cross-sectional view of a dual illumination-zone optical printhead assembly 700A, comprising an optical furnace 702 disposed between nucleation zone 124 and nozzle 126, in accordance with at least one implementation. In at least one implementation, dual illumination-zone optical printhead assembly 700A comprises most of the features of printhead assembly 100 described above. In at least one implementation, sidewall 704 of optical furnace 702 comprises optical fiber ports 706 configured to accept optical fiber couplers 708. In at least one implementation, optical fiber couplers 708 are configured to couple optical fibers to optical furnace 702 to create growth zone 710 (delineated by dashed region) during operation.

In at least one implementation, light emitted into optical furnace 702 may comprise a wavelength that causes nascent nanoparticles that nucleate within nucleation zone 124 to continue to grow within growth zone 710 by surface reactions with entrained unreacted gases carried toward nozzle orifice 130. In at least one implementation, the residence time within growth zone 710 may in part be determined by length L of optical furnace 702.

In at least one implementation, the size of growth zone 710 may be in part determined by the exit angle a of light cones exiting optical fibers attached to dual illumination-zone optical printhead assembly 700A by fiber couplers 708. The exit angle α may in part be determined by the numerical aperture of the optical fibers, which is determined by the refractive indices of the fiber core and cladding. For example, a large exit angle α may be approximately 130 degrees, assuming a core refractive index of approximately 1.5 and a cladding refractive index of approximately 1.2. In at least one implementation, refractive indices of both core and cladding materials may be tuned to adjust the exit angle α of light from the optical fibers so that maximal illumination of optical furnace 702 may be achieved.

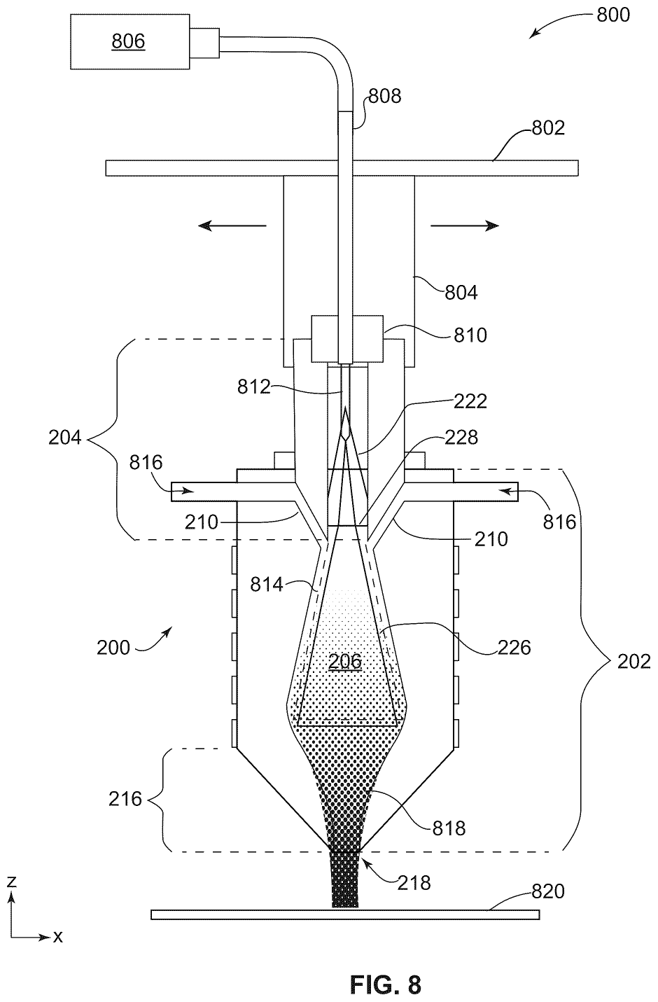

FIG. 7B illustrates a cross-sectional view of a dual illumination-zone optical printhead assembly 700B, comprising one or more collimating lenses 712 mounted within optical ports 714 disposed within sidewall 704 of optical furnace 702, in accordance with at least one implementation. In at least one implementation, dual illumination-zone optical printhead assembly 700B comprises collimating lenses 712 configured to collimate cones of light exiting optical fibers attached via optical fiber couplers 708 extending from optical ports 714. In at least one implementation, collimating lenses 712 are aspherical lenses configured to match the numerical aperture of optical fibers 720. While collimating lenses 712 are shown as aspherical lenses in the illustrative implementation, other suitable lens geometries. For example, a Powell geometry for collimating lenses 712 may be employed, in accordance with at least one implementation. In at least one implementation (e.g., in an aspherical geometry), lenses 712 are configured such that convex surfaces 716 face inwardly toward growth zone 710 within optical furnace 702, whereas flat surfaces 718 of lenses 712 face ends of optical fibers 720. During operation, cones of light having an exit angle α may impinge on flat surfaces 718. In at least one implementation, collimating lenses 712 may refract impinging light such that light exiting convex surfaces 716 is collimated (e.g., formed into a beam), creating a more uniform and intense illumination within optical furnace 702. While the figure shows two collimating lenses 712, any suitable number of collimating lenses 712 may be employed. For example, three or four collimating lenses 712 may be employed to more fully illuminate growth zone 710, thus injecting greater optical power to produce more mature nanoparticles prior to exiting the printhead through nozzle orifice 130. FIG. 8 illustrates a nanoparticle printer system 800, comprising optical printhead assembly 200, in accordance with at least one implementation. In at least one implementation, optical printhead assembly 200, described above, is attached to a gantry 802 via a plate 804. In at least one implementation, gantry 802 is operable to translate optical printhead assembly 200 along the x, y, and z axes. In at least one implementation, a light source 806 is optically coupled to lens 222 via an optical fiber 808. In at least one implementation, light source 806 is a laser light source, for example, a semiconductor laser, a CO₂ laser, an excimer laser, or a pumped crystal laser, operable to emit collimated light comprising infrared, visible, or ultraviolet wavelengths. In at least one implementation, light source 806 is operable to emit noncollimated light, for example, in the form of white light from a light-emitting diode (LED) source or a halogen lamp source; ultraviolet light from a mercury or xenon lamp, or an ultraviolet LED source; infrared light from an infrared incandescent source, such as a halogen lamp or LED source.

In at least one implementation, light source 806 is coupled to optical printhead assembly 200 via optical fiber 808 coupled to optical port 810. In at least one implementation, optical fiber 808 is any suitable single mode or multimode optical fiber. In at least one implementation, light source 806 may be directly attached to optics module 204 of optical printhead assembly 200. For example, light source 806 may be a module of suitable size that is operable to be mechanically affixed to optical module at optical port 810 such that it is optically aligned with lens 222.

In at least one implementation, lens 222 is operable to spread light beam 812 into light field 226, emanating base surface 228 of lens 222. In at least one implementation, light field 226 has a conical or trapezoidal shape to illuminate a large reaction volume within mixing chamber 206. In at least one implementation, mixing chamber 206 has a flared geometry to enable expansion of precursor gas flow within mixing chamber 206. Expansion of the gas flow may slow the velocity of the precursor flow to increase residence time within reaction zone 814, delineated in the figure by the dashed trapezoid. In at least one implementation, lens 222 is a Powell lens, operable to produce a quasi-two-dimensional trapezoidal light field. While a Powell lens is described, any suitable lens may be employed. For example, a cylindrical or hemicylindrical lens, an axicon lens or a plano-convex lens may be employed to obtain desired light field geometries.

In at least one implementation, precursor molecules may be introduced into mixing chamber 206 via conduits 816, which are fluidically coupled to precursor inlets 210 and in fluidic communication with mixing chamber 206. In at least one implementation, conduits 816 are coupled to gas sources (not shown), including one or more carrier gases, reactive gases such as oxygen, ozone, hydrogen, ammonia, hydrazine, reactive organic molecules, as well as precursor vapors or gases. Precursor molecules are in the gas phase and are generally vapors of liquid or solid-state materials. In at least one implementation, precursor molecules may be susceptible to interact with light, whereby one or more wavelengths contained in the light may induce photochemical reaction between precursor molecules with each other or with one or more reactive gases.

In at least one implementation, nanoparticle printer system 800 is operable to produce nanoparticle mass 818 within mixing chamber 206. In at least one implementation, nanoparticle mass 818 may increase in density as nanoparticles entrained in the gas flow move lower in reaction zone 814 and approach nozzle orifice 218. Nanoparticles may grow from supramolecular nuclei formed near the top of reaction zone 814. Such supramolecular nuclei may have diameters of 10 nanometers or less and may grow in size by colliding with other incipient nanoparticles within mixing chamber 206, or by heterogeneous surface reaction of precursor molecules occurring directly on the incipient nanoparticles within mixing chamber 206.

In at least one implementation, nanoparticles exit optical printhead assembly 200 through nozzle orifice 218, and impinge on substrate 820, proximal to nozzle orifice 218. In at least one implementation, a compact nanoparticles film may be deposited on substrate 820, where lines and other shapes of such a deposit may be written on substrate 820 by raster scanning optical printhead assembly 200 in a desired pattern. While nanoparticle printer system 800 includes optical printhead assembly 200 configured to produce nanoparticles internally, nanoparticle printer system 800 may employ optical printhead assembly 400 or optical printhead assembly 500, for example, where optical printhead assembly 400 and optical printhead assembly 500 are configured to produce nanoparticles externally by depositing unreacted precursor molecules on a substrate and simultaneously illuminating the deposited precursor molecules.

FIG. 8 is a flowchart 900 illustrating an exemplary method for writing nanoparticle patterns on substrates, in accordance with at least one implementation. The operations of flowchart 900 may be performed or controlled by hardware, software, or a combination of them. The method disclosed in the following paragraphs describes a nanoparticle film write procedure employing an optical printhead comprising an internal mixing chamber and reaction zone, such as any one of optical printhead assemblies 100, 200, or 300. It may be understood that aspects of the disclosed method may be adapted for optical printhead assembly 400 or optical printhead assembly 500, where the substrate is illuminated through the printhead, and nanoparticles are formed photochemically or thermally directly on the substrate.

At operation 902, a gas composition is introduced into an optical printhead (e.g., optical printhead assembly 100, shown in FIG. 1), where the gas composition comprises molecules of a precursor substance that can be reacted to form a solid substance. In at least one implementation, the optical printhead comprises a mixing chamber, such as mixing chamber 118, wherein precursor molecules may undergo photochemical reaction to form a solid substance when transiting through an illuminated reaction zone (e.g., reaction zone 124) within the mixing chamber.

In at least one implementation, the gas composition comprises a carrier gas and/or a reactive gas such as oxygen, volatile oxides of phosphorous or sulfur, such as sulfur dioxide; ozone; hydrogen and volatile hydrides such as ammonia, or hydrazine; halogens such as chlorine, bromine, and fluorine; and reactive organic compounds. In at least one implementation, a carrier gas may include relatively inert gases such as nitrogen, helium, or argon. The carrier gas may make up the majority of the gas composition, whereas the reactive components including precursor vapors may compose a minor fraction of the gas composition.

The precursor may include volatile halides, carbonyl complexes, as well as other volatile salts and complexes of transition metals and non-transition metals (e.g., group 1A-6A elements), as these substances are readily vaporized. For example, iron oxide precursor may be introduced as iron pentacarbonyl, a volatile iron complex that is thermally labile. Synthesis of such nanocrystalline film may employ an infrared (IR) light source, such as a carbon dioxide (CO₂) laser or another suitable IR source. Another example may include formation of iron-carbon nanoparticles, formed by ultraviolet photolysis of iron pentacarbonyl as the volatile precursor substance in the presence of carbon tetrachloride, also a volatile substance. A further example includes deposition of highly oriented nanocrystalline silicon by laser photolysis of silicon tetrahydride as the volatile precursor substance, using a deep ultraviolet light source (e.g., an excimer laser).

At operation 904, the gas composition is illuminated by shining light from a light source optically coupled to the optical printhead. In at least one implementation, the optical printhead is a single illumination zone optical printhead, such as any one of disclosed embodiments of optical printhead assemblies 100, 200, 300, 400, 500, and 600. In at least one implementation, the optical printhead is a dual illumination zone optical printhead (e.g., such as dual illumination zone optical printhead assemblies 700A or 700B), operated in a single illumination mode whereby only the reaction zone in the mixing chamber is illuminated. An exemplary configuration is shown in FIG. 8 for a single illumination zone optical printhead, where nanoparticle printer system 800 comprises light source 806 optically coupled to optical printhead assembly 200 via optical fiber 808. Light source 806 may be a laser or a non-coherent light source, such as a halogen or xenon lamp. In at least one implementation, the light source may be directly affixed to the printhead, as noted above. Light from the light source is directed to pass through an optical lens seated within an optical module (e.g., optics module 104) portion of the printhead. In at least one implementation, the printhead may be unitary structure (a single piece, omitting separate modules), comprising a passage through which light transits to the optical lens, such as lumen 106.

In at least one implementation, the optical lens may be a cylindrical or hemicylindrical lens, operable to produce a quasi-two-dimensional light field. For example, the light field may be constrained to a line in one dimension and be expanded out in the other two dimensions. A similar light field may be produced by a Powell lens. Within the mixing chamber, a trapezoidal light field may develop, where the taper of the trapezoidal light field may approximate a flare angle of the mixing chamber. In this manner, a maximum area within the mixing chamber may be occupied by the light field to maximize a reaction volume for the highest rate of nanoparticle formation. Such a geometry may best suit a printhead having a flat rectangular cross section.

In at least one implementation, the optical lens may be a plano convex lens. Such a lens may form a conical light field and reaction volume, having a substantially cylindrical symmetry. Such a cylindrical reaction volume geometry may best suit a printhead also having a cylindrical geometry. In at least one implementation, the optical lens is an axicon lens. In at least one implementation, an axicon lens may produce a substantially hollow cone of light, where a top portion of the cone of light (e.g., nearest the lens) is solid. A substantial volume of a mixing chamber having a cylindrical symmetry may be illuminated by a light field produced by an axicon lens.

In at least one implementation, the optical printhead is a dual illumination zone-optical printhead such as dual illumination zone optical printhead assemblies 700A or 700B. In at least one implementation, the dual illumination zone optical printhead comprises a reaction zone in a mixing chamber and a growth zone within an optical furnace (e.g., optical furnace 702) downstream of the mixing chamber (e.g., mixing chamber 118, see FIGS. 7A and 7B). In at least one implementation, the growth zone enables further growth of nascent nanoparticles that may have nucleated within the reaction zone (e.g., reaction zone 124). In at least one implementation, the dual illumination zone optical printhead, is illuminated by a first light source directed through the optics module (e.g., optics module 104) and through the lens (e.g., lens 112) within the lumen (e.g., lumen 106) of the optics module. In at least one implementation, the light source produces a first light field within the reaction zone (e.g., reaction zone 124), whereby the light field comprises at least one wavelength, whereby the at least one wavelength is a first wavelength operable to engender photochemical or thermochemical reactions with gaseous nanoparticle precursors.

In at least one implementation, the dual illumination zone optical printhead is illuminated by a second light source operable to produce light directed into the optical furnace (e.g., optical furnace 702) through optical windows within a sidewall surrounding the optical furnace. In at least one implementation, light produced by the second light source produces a second light field within the growth zone (e.g., growth zone 710) within the optical furnace. In at least one implementation, the second light field comprises a second wavelength, whereby the second wavelength is operable to sustain nanoparticle growth within the growth zone (e.g., growth zone 710) of the dual illumination zone optical printhead. In at least one implementation, the second wavelength is different from the first wavelength. In at least one embodiment, the second wavelength is substantially the same as the first wavelength.

In at least one implementation, optical windows may comprise optical fiber couplers (e.g., optical fiber couplers 708) within sidewall 704 surrounding optical furnace 702. In at least one implementation, optical windows may comprise collimating lenses (e.g., collimating lenses 712) mounted within optical ports (e.g., optical ports 714) within sidewall 704.

At operation 906, a gaseous stream of nanoparticles (e.g., nanoparticle mass 818) is formed in the gas phase (e.g., homogeneous reactions) within the mixing chamber. Molecules of the newly formed solid material may coalesce to form nanoparticle nuclei. Exemplary syntheses of industrially important nanoparticles are the following:

In at least one implementation, synthesis of tungsten nanoparticles may be carried out by introducing a gas composition comprising a mixture of tungsten hexafluoride (WF₆) precursor and hydrogen gas into the mixing chamber. In at least one implementation, WF₆ precursor may be converted to tungsten metal by photodissociation of WF₆ mediated by an argon-fluoride excimer laser at a wavelength of 193 nm. A mechanism of metallic tungsten formation may incur multiphoton dissociation of WF₆ to lower coordination numbers, or a single photon reaction involving hydrogen, yielding hydrogen fluoride. Tungsten oxide may be formed by addition of oxygen or reactive oxygen compounds such as ozone into the gas composition.

Iron and iron-carbon nanoparticles may be synthesized for production of steel structures amenable to 3D printing. A gas composition comprising iron pentacarbonyl (Fe(CO)₅) in an argon carrier gas may be employed. An exemplary concentration of Fe(CO)₅ may be 10 millibar in 1 bar of argon. Other inert gases may be substituted for argon, such as helium. In one at least one implementation, illumination of the reaction zone is performed by a 248 nm line of an excimer laser pulsed with pulse widths of 40 nanoseconds, at energy intensities ranging between 2 and 60 mJoules/cm². It may be understood that these parameter values are not fixed and may be varied to obtain desired results. Clusters of iron nanoparticles may be obtained, where individual nanoparticles may be larger than 10 nm. Exposure of the nanoparticles to air may induce oxidation of pure iron nanoparticles, forming various iron oxide phases. Other routes to synthesis of iron nanoparticles include ultraviolet photodissociation of ferrocene. Iron-carbon nanoparticle compositions may be obtained by photodissociation of ferrocene (Fe(C₅H₅)₂) and Fe(CO)₅ in the presence of carbon tetrachloride (CC14). Photolysis may be induced by ultraviolet light, for example, from a pulsed Nd:YAG laser (e.g., 266 nm, fourth harmonic). Iron-carbon nanoparticles may also be obtained by exposing Fe(CO)₅+CS₂ to near-UV illumination from a mercury lamp at 460 nm, for example. In at least one implementation, a sensitizer may be introduced to aid in light absorption.

At operation 908, nanoparticles are deposited on a substrate. In at least one implementation, a gaseous stream containing the nanoparticle mass exits through a nozzle orifice (e.g., nozzle orifice 218) of the printhead. In at least one implementation, the nozzle orifice is proximal to the substrate. For example, the nozzle orifice may be maintained at a distance of 1 mm or less above the substrate. Deposition rates may vary depending on reaction rates controlled by light intensity, temperature and concentration of precursors and other reactive species in the gas composition.

In at least one implementation, the nanoparticle printer system may be employed for 3D printing of metals and ceramics. Nanoparticulate macrostructures may be created by writing with the printhead mounted on a gantry system capable of translating in three dimensions (e.g., gantry 802). For example, deposition rates of 1000 angstroms per minute or greater may be achieved.

In at least one implementation, nanoparticle printer system may be integrated with commercial metal printing systems, for example. Nanoparticles may be directly jetted into the melt pool. The printing system can also be integrated with polymer 3D printing systems and dope nanomaterials into polymers to produce composites. In at least one implementation, metal structures may be produced layer-by-layer employing additive manufacturing techniques such as 3D printing, whereby successive layers may be doped by jetting oxide nanoparticles on the layers' surfaces. After completion of the metal structure, subsequent laser treatment may cause melting and dissolution and/or dispersion of nanoparticles into the bulk of the layers, enabling a homogenization of the dopant materials into the bulk of the metal structure. In at least one implementation, the printer nozzle can also be directed into a melt pool of the metal or alloy for in-situ doping of nanoparticles into the liquid melt, creating functional alloys or metal matrix composites.

For example, oxide nanoparticles such as yttrium oxide (e.g., Y₂O₃) and zirconium dioxide (e.g., ZrO₂), as well as many other oxides, can be doped into pure metals or alloys such as stainless steel, aluminum, copper, tungsten, etc. In at least one implementation, doping of pure metals and metal alloys with nanoparticles comprising rare earth and transition metal oxides may improve mechanical properties, radiation resistance, and high temperature performance of pure metals and alloys. For polymers, similar improvement of material properties may be obtained by nanoparticle doping. For example, polylactic acid (PLA) can be doped with nanoparticles comprising titanium dioxide (e.g., TiO₂) to improve its ultraviolet (UV) resistance, whereas doping with nanoparticles comprising tungsten oxide (e.g., WO₃) can improve its radiation resistance.

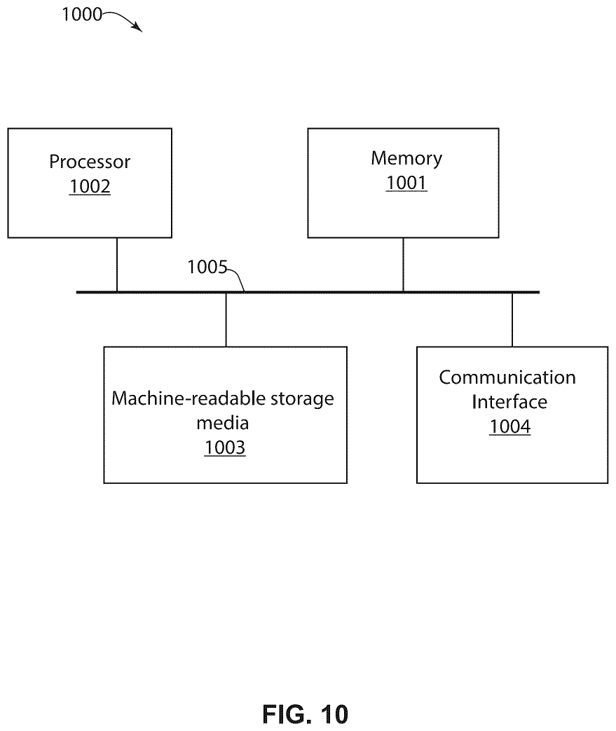

FIG. 10 illustrates a processor system 1000 with a machine-readable storage medium having machine-readable instructions that when executed cause a microcontroller (e.g., processor 10**02) in a circuit board of a control unit for nanoparticle printer system 800 to execute machine-readable instructions according to the method summarized by flowchart 900, In accordance with at least one implementation. In at least one implementation, microcontroller may be configured to measure and report intra-bandgap density of states. In at least one implementation, processes described herein may be stored in a machine-readable medium (e.g., 1003) as computer-executable instructions. In at least one implementation, a machine-readable storage medium may be random access memory (RAM), for example. In at least one implementation, processor system 1000 comprises memory 1001, processor 1002, machine-readable storage medium 1003 (also referred to as tangible machine-readable medium), communication interface 1004 (e.g., wireless or wired interface), and network bus 1005 coupled together as shown.

In at least one implementation, processor 1002 is a Digital Signal Processor (DSP), an Application Specific Integrated Circuit (ASIC), a general-purpose Central Processing Unit (CPU), or a low power logic implementing a simple finite state machine to perform various processes described herein.

In at least one implementation, various logic blocks of processor system 1000 are coupled together via network bus 1005. Any suitable protocol may be used to implement network bus 1005. In at least one implementation, machine-readable storage medium 1003 includes instructions (also referred to as program software code/instructions) for raster scanning an optical printhead (e.g., optical printhead assembly 200) to deposit nanoparticles in a patterned coded into software stored in machine-readable storage medium 1003.

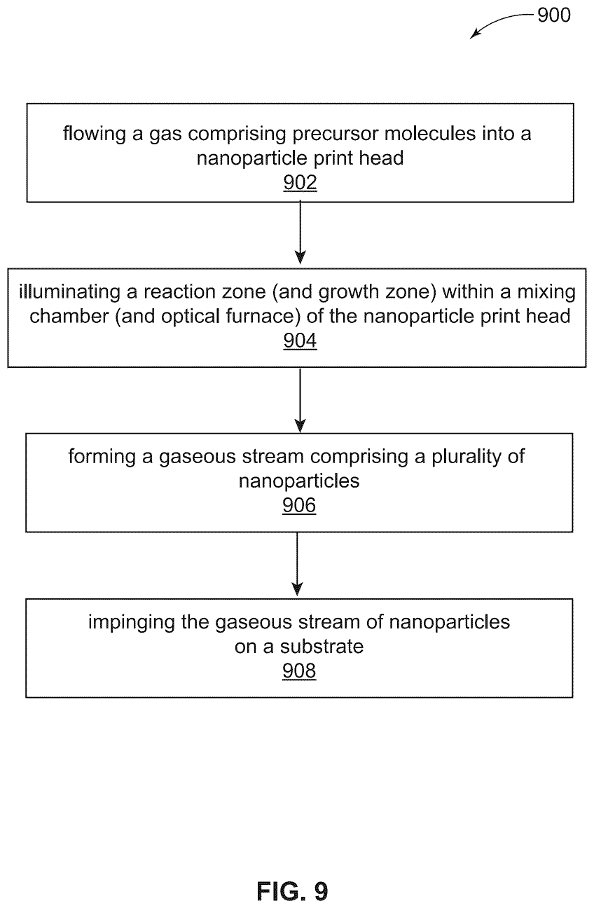

In at least one implementation, machine-readable storage media 1003 is a machine-readable storage media with instructions for positioning an optical printhead between in nanoparticle printer system 800. Machine-readable medium 1003 has machine-readable instructions, that when executed, cause processor 1002 to perform the method discussed herein (e.g., see FIG. 9).

In at least one implementation, program software code/instructions associated with various implementations may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In some implementations, program software code/instructions associated with processes of various implementations are executed by processor system 1000.

In at least one implementation, machine-readable storage media 1003 is a computer executable storage medium. In at least one implementation, program software code/instructions associated with various implementations are stored in computer executable storage medium 1003 and executed by processor 1002. Here, computer executable storage medium 1003 is a tangible machine-readable medium 1003 that can be used to store program software code/instructions and data that, when executed by a computing device, causes one or more processors (e.g., processor 1002) to perform a process.

In at least one implementation, tangible machine-readable medium 1003 may include storage of executable software program code/instructions and data in various tangible locations, including for example, ROM, volatile RAM, non-volatile memory, and/or cache, and/or other tangible memory as referenced in present application. Portions of this program software code/instructions and/or data may be stored in any one of these storage and memory devices. In some implementations, program software code/instructions can be obtained from other storage, including, e.g., through centralized servers or peer to peer networks and like, including Internet. Different portions of software program code/instructions and data can be obtained at different times and in different communication sessions or in the same communication session.

In at least one implementation, software program code/instructions associated with various implementations can be obtained in their entirety prior to execution of a respective software program or application. Alternatively, portions of software program code/instructions and data can be obtained dynamically, e.g., just in time, when needed for execution. Alternatively, some combination of these ways of obtaining software program code/instructions and data may occur, e.g., for different applications, components, programs, objects, modules, routines, or other sequences of instructions or organization of sequences of instructions, by way of example. Thus, it is not required that data and instructions be on a tangible machine-readable medium 1003 in entirety at a particular instance of time.

In at least one implementation, tangible machine-readable medium 1003 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMs), Digital Versatile Disks (DVDs), etc.), among others. In at least one implementation. software program code/instructions may be temporarily stored in digital tangible communication links while implementing electrical, optical, acoustical, or other forms of propagating signals, such as carrier waves, infrared signals, digital signals, etc. through such tangible communication links.

In some instances, well-known methods and devices are shown in block diagram form, rather than in detail, to avoid obscuring at least one implementation. Reference throughout this specification to “an implementation,” “one implementation,” “in at least one implementation,” or “some implementations” means that a particular feature, structure, function, or characteristic described in connection with implementation is included in at least one implementation. Thus, appearances of phrase “in an implementation,” “in at least one implementation,” or “in one implementation” or “some implementations” in various places throughout this specification are not necessarily referring to same implementation of disclosure. Furthermore, particular features, structures, functions, or characteristics may be combined in any suitable manner in one or more implementations. For example, a first implementation may be combined with a second implementation anywhere particular features, structures, functions, or characteristics associated with two implementations are not mutually exclusive.

As used in herein, singular forms “a,” “an,” and “the” are intended to include plural forms as well, unless context clearly indicates otherwise. It will also be understood that term “and/or” as used herein refers to and encompasses all possible combinations of one or more of associated listed items.

Here, “coupled” and “connected,” along with their derivatives, may be used herein to describe functional or structural relationships between components. These terms are not intended as synonyms for each other. Rather, in particular implementations, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that two or more elements co-operate or interact with each other (e.g., as in a cause an effect relationship).

Here, “over,” “under,” “between,” and “on” as used herein refer to a relative position of one component or material with respect to other components or materials where such physical relationships are noteworthy. For example, in context of materials, one material or material disposed over or under another may be directly in contact or may have one or more intervening materials. Moreover, one material disposed between two materials may be directly in contact with two layers or may have one or more intervening layers. In contrast, a first material “on” a second material is in direct contact with that second material/material. Similar distinctions are to be made in context of component assemblies. As used throughout this description, and in claims, a list of items joined by term “at least one of” or “one or more of” can mean any combination of listed terms.

Here, “adjacent” generally refers to a position of a thing being next to (e.g., immediately next to or close to with one or more things between them) or adjoining another thing (e.g., abutting it).

Here, “signal” may refer to current signal, voltage signal, magnetic signal, or data/clock signal.

Here, “device” may generally refer to an apparatus according to context of usage of that term. For example, a device may refer to a stack of layers or structures, a single structure or layer, a connection of various structures having active and/or passive elements, etc. Generally, a device is a three-dimensional structure with a plane along x-y direction and a height along z direction of an x-y-z Cartesian coordinate system. In at least one implementation, plane of device may also be plane of an apparatus which comprises device.

Unless otherwise specified in explicit context of their use, terms “substantially equal,” “about equal,” and “approximately equal” mean that there is no more than incidental variation between two things so described. Such variation is typically no more than +/−10% of a predetermined target value.

Here, “left,” “right,” “front,” “back,” “top,” “bottom,” “over,” “under,” and similar terms are used for descriptive purposes and not necessarily for describing permanent relative positions. For example, terms “over,” “under,” “front side,” “back side,” “top,” “bottom,” “over,” “under,” and “on” as used herein refer to a relative position of one component, structure, or material with respect to other referenced components, structures, or materials within a device, where such physical relationships are noteworthy. These terms are employed herein for descriptive purposes only and predominantly within context of a device z-axis and therefore may be relative to an orientation of a device. Hence, a first material “over” a second material in context of a figure provided herein may also be “under” second material if device is oriented upside-down relative to context of figure provided. Similar distinctions are to be made in context of component assemblies.

Here, a device that is “configured to” perform a task or function may be configured (e.g., programmed and/or hardwired) at a time of manufacturing by a manufacturer to perform the function. In at least one example, the device may be configurable (or reconfigurable) by a user after manufacturing to perform the function and/or other additional or alternative functions. In at least one example, the configuring may be through firmware and/or software programming of the device, through a construction and/or layout of hardware components and interconnections of the device, or a combination thereof.

Here, “between” may be employed in context of z-axis, x-axis, or y-axis of a device. A material that is between two other materials may be in contact with one or both of those materials. In another example, a material that is between two or other material may be separated from both of other two materials by one or more intervening materials. A material “between” two other materials may therefore be in contact with either of other two materials. In another example, a material “between” two other materials may be coupled to other two materials through an intervening material. A device that is between two other devices may be directly connected to one or both of those devices. In another example, a device that is between two other devices may be separated from both of other two devices by one or more intervening devices.

What is claimed is:

1. A printhead for producing nanoparticles, comprising:
a reaction module comprising a mixing chamber, wherein one or more inlets open into the mixing chamber, wherein a nozzle is coupled to the mixing chamber; and
an optics module extending into the reaction module, wherein the optics module comprises a lens within a lumen, wherein the lumen opens into the mixing chamber.

2. The printhead of claim 1, wherein the optics module is seated within a receptacle at a top portion of the reaction module, wherein a first opening of the lumen is configured as an optical port to receive an optical fiber or a light source module, and wherein the optical fiber or the light source module are affixed to the optics module.

3. The printhead of claim 2, wherein the optical fiber or the light source module is aligned optically to the lens.

4. The printhead of claim 3, wherein a second opening of the lumen opens into the mixing chamber, and wherein the lens is disposed within the lumen proximal to the second opening, proximal to the mixing chamber.

5. The printhead of claim 1, wherein one or more second inlets open into the lumen, and wherein the one or more second inlets are disposed above the lens.

6. The printhead of claim 1, wherein the lens is a Powell lens, an axicon lens, a cylindrical lens, an aspherical lens, or a plano-convex lens.

7. The printhead of claim 1, further including an optical furnace, wherein the optical furnace is between the mixing chamber and the nozzle.

8. The printhead of claim 7, wherein the optical furnace comprises one or more optical couplers within a sidewall surrounding the optical furnace.

9. The printhead of claim 8, wherein the one or more optical couplers comprise a collimating lens.

10. A nanoparticle printer, comprising:
a printhead, comprising:
a reaction module comprising a mixing chamber, wherein one or more inlets are disposed within a wall of the reaction module and are coupled with the mixing chamber; and
an optics module affixed to the reaction module, wherein the optics module comprises a lens within a lumen, wherein the lumen extends from a first opening through a first portion of the optics module to a second opening through a second portion of the optics module, wherein the second portion is opposite the first portion;
a light source aligned to the lens; and
at least one conduit coupled to the one or more inlets, wherein the at least one conduit is coupled to a gas source, wherein the gas source comprises at least one nanoparticle precursor substance.

11. The nanoparticle printer of claim 10 wherein an optical fiber is coupled to the light source, and wherein the optical fiber extends through the first opening into the lumen of the optics module and is optically aligned to the lens.

12. The nanoparticle printer of claim 10, wherein at least one of the one or more inlets is disposed within the optics module, wherein at least one of the one or more inlets is coupled to a carrier gas source.

13. The nanoparticle printer of claim 10, wherein the light source is attached to the optics module over the first opening of the lumen, wherein the light source is optically aligned to the lens.

14. The nanoparticle printer of claim 13, wherein the light source comprises a non-coherent light source device, a semiconductor laser device, or a pumped crystal laser device.

15. A method for using a nanoparticle printer, comprising:
flowing a gas comprising a vapor of a precursor substance into a nanoparticle printhead, wherein the nanoparticle printhead comprises:
a reaction module comprising a mixing chamber, wherein one or more inlets are disposed within a wall of the reaction module and are coupled with the mixing chamber, wherein a nozzle comprising a nozzle orifice is fluidically coupled to the mixing chamber; and
an optics module affixed to the reaction module, wherein the optics module comprises a lens within a lumen, wherein the lumen extends from a first opening through a first portion of the optics module to a second opening through a second portion of the optics module, wherein the second portion is opposite the first portion;
illuminating a reaction zone within the mixing chamber with a light comprising a wavelength that interacts with the precursor substance, wherein the precursor substance reacts photochemically or thermally to form a plurality of nanoparticles; and
forming a gaseous stream comprising the plurality of nanoparticles, wherein the gaseous stream comprising the plurality of nanoparticles is directed to impinge on a substrate adjacent to the nozzle orifice of the reaction module.

16. The method of claim 15, wherein forming the gaseous stream comprising the plurality of nanoparticles comprises forming the gaseous stream within the mixing chamber of the nanoparticle printhead, wherein a carrier gas is mixed with the plurality of nanoparticles.

17. The method of claim 16, wherein illuminating the reaction zone within the mixing chamber comprises creating a light field within the mixing chamber by shining the light comprising the wavelength that interacts with the precursor substance through the lens.

18. The method of claim 17, further including illuminating a growth zone, wherein the growth zone is within an optical furnace disposed between the mixing chamber and the nozzle orifice.

19. The method of claim 18, wherein the light field is a first light field, the wavelength is a first wavelength, and wherein illuminating the growth zone comprises creating a second light field within the optical furnace, wherein the second light field is created by shining a second light into the optical furnace via one or more optical fibers coupled to the optical furnace.

20. The method of claim 19, wherein the one or more optical fibers are optically coupled to a light source having a second wavelength, wherein:
the first wavelength is substantially same as the second wavelength; or
the first wavelength is different from the second wavelength.
